(19) United States
(12) Patent Application Publication
(10) Pub. No.: US 2009/0035455 A1
(43) Pub. Date: Feb. 5, 2009

(54) Adhesive bleed prevention method and product produced from same

(75) Inventors: Roy H. Magnuson, Endicott, NY (US); Luis J. Matienzo, Endicott, NY (US)

Correspondence Address: LAWRENCE R. FRALEY;Hinman, Howard & Kattell, LLP, 700 Security Mutual Building, 80 Exchange Street, Binghamton, NY, 13902-5250, US

(73) Assignee: Endicott Interconnect Technologies, Inc., Endicott, NY (US)

(21) Appl. No.: 11/882,149

(22) Filed: Jul. 31, 2007

(51) Int. Cl. H05K 3/00; B32B 15/04

(52) U.S. Cl. 427/97.3; 428/457

(57) ABSTRACT

A method of preventing adhesive bleed onto the metal (e.g., gold) surfaces of a plurality of electrical conductors (e.g., wire-bond pads) positioned on a dielectric substrate when positioning an electronic component onto the dielectric substrate and electrically coupling (e.g., wire-bonding) the component to the metal surfaces. The method includes contacting the metal surfaces with a chemical composition which comprises a minor amount of a surface active agent (e.g., a thiol) and the remainder substantially being a non-reactive solvent (e.g., methanol). A circuitized substrate produced using this method is also provided.

### TECHNICAL FIELD

This invention relates generally to bleed prevention of organic material onto the metal surfaces of conductors on a substrate such as circuitized substrates, e.g., printed circuit boards and chip carriers, and particularly to the treatment of such metal surfaces in order to prevent bleeding of such material onto same.

### BACKGROUND OF THE INVENTION

It is known in the circuitized substrate field of printed circuit boards and chip carriers to mount semiconductor chips (also referred to as I/Cs for Integrated Circuits) onto the exterior surfaces of such substrates. Electrical coupling of the chips is accomplished typically by either: (1) a plurality of solder balls arranged in an array under the chip to directly couple chip contact sites to substrate conductor pads located directly beneath the chip; or (2) by what are referred to as wire-bonds in which extremely thin wires are used to couple the chip's contact sites to corresponding wire-bond pads on the substrate. In the case of the latter, the chip is typically mounted directly onto the surface of the substrate using an adhesive while the wires connect the sites to pads strategically positioned about the chip in a predetermined pattern. When mounting chips on such substrates using the wire-bond approach, one known procedure in particular utilizes an epoxy adhesive to bond the chip either to gold plating on a planar surface of a substrate, or onto copper or some dielectric material in a cavity formed in the substrate. A particular problem encountered when using such bond techniques is the tendency of some of the components of the epoxy adhesive to “bleed” and spread onto the wire bond (and perhaps other conductive surfaces, such as ground and/or voltage rings) located near the chip. This “bleed” may cause the surface of the conductive bond pads as well as the other metal surfaces to be unreceptive to the bonding of the wires thereto, thereby preventing an effective connection or connections and resulting in a defective final product. This understandably results in excessive scrap rates and undesirable added costs to the manufacturer.

One known procedure for solving the above and other problems associated with wire bonding chips in such an environment is to treat the substrate (and conductor(s)) surface(s) with a fluorine-containing plasma which reacts with both the organic portion of the substrate and the conductor surface(s). Using such a plasma treatment results in the fluorine containing moieties settling on the noble (typically gold) surface(s) of the wire bond pads and other noble surfaces to render these less susceptible to wetting by the adhesive bleed. Such plasma treatment is not entirely successful on some occasions however because the fluorine containing moieties tend not to strongly bond to the gold. These may then be relatively easily removed with organic solvents during processing before chip bonding occurs. It is further believed that such fluorine-containing plasma treatment processes may have a deleterious effect on the dielectric surfaces, sometimes to the extent that the subsequent application of encapsulating material is adversely affected. The reason for this is believed to be the incorporation of fluorine atoms into the structure of the dielectric organic layer.

The study of “Self-Assembled Monolayers (SAMs) is an area also known in the art. Such monolayers are typically formed of molecules each having a functional group that selectively attaches to a particular surface, the remainder of each molecule interacting with neighboring molecules in the monolayer to form a relatively ordered (aligned) array. Such SAMs are formed when the composition including these molecules have been located on the surfaces being treated for a predetermined time period (usually hours) and have been formed on a variety of substrates including metals, silicon dioxide, gallium arsenide, and others and have been applied to surfaces in predetermined patterns in a variety of ways including simple flooding and irradiative patterning. In one known approach, the method includes treating wire-bond pads with a chemical composition characterized by a molecule having at least one group, such as a mercaptan or disulfide, connected to a hydrocarbon moiety. The affinity of the thiol or sulfur-containing portion of the molecule chemically bonding with the noble metal provides a relatively strong attachment of the molecule to the metal surface. The hydrocarbon segment presents a surface on the noble metal that has the characteristics of the hydrocarbon portion of the molecule which has a low surface tension, and, thus, prevents wetting of the noble metal by an epoxy adhesive component. These SAMs, after providing bleed protection, may then self-desorb from the surfaces during the following wire bonding process.

It is, therefore, an object of the present invention to provide a method and structure for substantially reducing or eliminating the wettability of metal surfaces, particularly noble metal surfaces, and specifically gold or other noble metal surfaces, to organic materials, particularly any components of an adhesive, such as an epoxy used for attaching a semiconductor chip to a substrate.

The following patents describe various surface treatment procedures. The citation thereof is not an admission that any are prior art to the presently claimed invention.

In U.S. Pat. No. 5,208,067, there is described a silicon modified organic surface roughened by treatment with an oxygen containing plasma. If necessary, the organic surface may be silicon-modified by treatment with a silicon containing material prior to the plasma treatment. The roughened organic surface provides improved adhesion to other organic surfaces and to deposited metals.

In U.S. Pat. No. 5,283,119, there is described a method directed to treating the surfaces of rubber-reinforcing materials with a gas plasma to activate the surfaces to make these more receptive to adhesives. Optionally the surfaces of the reinforcing materials may be exposed to a polymerizing gas plasma such as a thio-carbon to coat the surfaces of the reinforcing material with substances that promote adhesion to rubber. The treated surfaces have been shown to adhere directly to rubber when vulcanized in the normal fashion.

In U.S. Pat. No. 5,487,810, there is described a method to improve the adhesion of coatings, especially metal coatings, to the surfaces of plastic components, the latter being pre-treated in low-pressure plasma with a process gas containing sulphur hexafluoride which is substantially free of oxygen. The plastic surfaces are kept free of fluorine deposits or inclusions during the pre-treatment.

In U.S. Pat. No. 5,514,501, there is described a process for creating a two dimensional spatial distribution pattern of different thiolate molecules on a substrate by illuminating a surface of a self-assembled monolayer of a first thiolate compound in the presence of oxygen with high frequency electromagnetic radiation distributed according to a desired pattern, and subsequently immersing the illuminated substrate in a solution of a second thiolate compound so that molecules of the first thiolate compound in illuminated areas of the monolayer are exchanged for molecules of said second thiolate compound; and a patterned biomolecular composite formed of a substrate which forms a self-assembled thiolate monolayer when immersed in a solution of a thiolate forming compound. A thiolate monolayer is deposited on the substrate and composed of patterned areas of first and second thiolate compounds, respectively, the first thiolate compound having an affinity for specifically or nonspecifically adsorbing a biological molecule, and the second thiolate compound having essentially no affinity for the biological molecule. At least one biological material is adsorbed in a corresponding pattern on the patterned areas of the first thiolate compound in the thiolate monolayer.

In U.S. Pat. No. 5,523,878, there is described a method of forming a monomolecular coating for surfaces of contacting elements of micro-mechanical devices, specifically, devices that have moving elements that contact other elements and that tend to stick as a result of the contact. The method uses liquid deposition, with the device being placed in a solution that contains a precursor to the formation of the coating. The precursor is chosen based on coordination chemistry between the precursor and the surface to be coated.

In U.S. Pat. No. 5,719,087, there is described a protective cap of dielectric material which is deposited by plasma-enhanced chemical vapor deposition on the surface of electrical bonding pads of semiconductor integrated circuits prior to deposition of the final passivation layer. The protective cap serves to isolate the pad surface from electrochemical or other interaction with the etching solution used to open contact holes through the passivation layer. This prevents the formation of surface damage and residues on the pad which lead to yield and reliability problem with integrated circuits.

In U.S. Pat. No. 5,756,380, there is described a method for making moisture resistant semiconductor devices having organic substrate targets, each of the interfaces within a semiconductor device having the potential for delamination and cracking. An organic substrate is designed to include a solid pad having a chemically created oxide layer formed thereon. A silicone-based die attach material is dispensed and gelled very soon after dispensing to prevent excessive bleed. A semiconductor die is mounted to the substrate after undergoing a cleaning operation to remove contaminants from the backside of the die. Prior to molding compound encapsulation and subsequent to die attach material cure, the substrate is cleaned to improve adhesion to the die attach material fillet

In U.S. Pat. No. 5,731,547, there is described a circuitized substrate having conductive circuitry thereon and a barrier located adjacent at least portions of the circuitry to serve as an effective constraint for liquid material (e.g., encapsulant) applied to cover and protect the circuitry. The barrier can be formed concurrently with circuitry formation and formed of materials (e.g., copper, nickel, gold) similar to those used for the circuitry. The barrier is of two-part construction and of a particular shape wherein one part affords a greater surface tension than the other such that the material may actually lie on one part while being prevented from engagement with the other. Providing such dual (or “progressive”) surface tension successfully constrains the liquid material at least until solidification thereof occurs.

In U.S. Pat. No. 5,900,160, there is described a method of forming a patterned self-assembled monolayer on a surface and derivative articles. According to one version, an elastomeric stamp is deformed during and/or prior to using the stamp to print a self-assembled molecular monolayer on a surface. According to another method, during monolayer printing the surface is contacted with a liquid that is immiscible with the molecular monolayer-forming species to effect controlled reactive spreading of the monolayer on the surface. Methods of printing self-assembled molecular monolayers on nonplanar surfaces and derivative articles are provided, as are methods of etching surfaces patterned with self-assembled monolayers, including methods of etching silicon. Optical elements including flexible diffraction gratings, mirrors, and lenses are provided, as are methods for forming optical devices and other articles using lithographic molding. A method for controlling the shape of a liquid on the surface of an article is provided, involving applying the liquid to a self-assembled monolayer on the surface, and controlling the electrical potential of the surface.

In U.S. Pat. No. 5,910,341, there is described a method for preparing a circuitized organic substrate for the subsequent deposition of an adhesive thereon. The method comprises exposing the circuitized substrate to a plasma formed from a gas mixture comprising a fluorine-containing entity. Preferably, the gas mixture used to form the plasma also comprises oxygen. It has been determined that treatment of the circuitized substrate with a plasma formed from a gas mixture comprising at least 20% by volume of the fluorine-containing entity and, preferably, up to about 80% by volume of oxygen reduces the spread of an adhesive deposited on the surface of the organic substrate. It has also been determined that such treatment does not adversely affect the subsequent bonding of wires to the wire bond sites that are present on the surface of the substrate. U.S. Pat. No. 6,046,500 is a divisional of U.S. Pat. No. 5,910,341 and provides similar teachings.

In U.S. Pat. No. 6,102,521, there is described treatment of the inner and outer surfaces of an orifice plate for ink-jet pens with self-assembled monolayers. The outer surface of a gold-plated orifice plate is treated with self-assembled monolayers to control wettability of the surface in order to reduce the accumulation of residual ink. The inner surface is treated with self-assembled monolayers to improve and control drop ejection. Various monolayers can also be used on the inner surface allowing for greater flexibility in controlling the steady state firing rate and uniformity of drops from a pen. In addition, treatment of orifice plate surfaces with self-assembled monolayers inhibits corrosion and contamination of the plate while presenting a uniform surface for the ink. The self-assembled monolayers include thiols, disulfides, and sulfinates, having terminal functional groups which determine the wettability of the surface. A chemical bond is formed between the gold on the orifice plate and the thiol, disulfide, or sulfinate group of the monolayer compounds. The terminal functional group of the monolayer compound is therefore oriented away from the surface of the orifice plate and renders the surface either wetting or nonwetting depending on whether the term group has hydrophobic or hydrophilic characteristics.

In U.S. Pat. No. 6,252,307, there is described both method and structure for preventing wetting or bleed of an adhesive, such as an epoxy, onto noble metal wire bond pads on the surface of a dielectric substrate when attaching a chip to the substrate. The method includes treating the wire bond pads with a chemical composition which prevents bleeding onto the surfaces of the wire bond pads by a component of the epoxy. The chemical composition is a chemical which will provide “Self-Assembled Monolayers” (SAMs) on the surface of the gold. These compositions are characterized by a molecule having at least one group, such as a mercaptan or disulfide, connected to a hydrocarbon moiety chain. The affinity of the thiol or sulfur-containing portion of the molecule chemically bonding with the noble metal provides a relatively strong attachment of the molecule to the metal surface. The hydrocarbon segment presents a surface on the noble metal that has the characteristics of the hydrocarbon portion of the molecule which has a low surface tension, and, thus, prevents wetting of the noble metal by an epoxy adhesive component. The SAMs, once these provide protection from the bleed of the die attach adhesives, self desorb during the wire bonding or soldering temperatures. U.S. Pat. No. 6,420,253 is related to U.S. Pat. No. 6,252,307 and provides similar teachings.

As defined herein, the present invention is a new composition which includes a large percentage (by weight) of a non-reacting solvent and a minor percentage (defined below) of a surface active agent, which, when applied to a precious metal surface, prevents bleed of adhesive onto the surface to the extent that effective wire-bonding onto this surface may be accomplished. It is believed that such a composition and method of applying same will represent significant advancements in the art.

### OBJECTS AND SUMMARY OF THE INVENTION

It is a primary object of this invention to enhance the art of preventing adhesive bleed onto conductive surfaces of circuitized substrates.

It is another object of this invention to provide a new composition able to prevent such bleeding in an effective manner and which may be produced at relatively low cost.

It is still another object of this invention to provide a method of applying such a composition which may be performed in a relatively facile manner, and thus is readily adaptable to mass production.

According to one aspect of this invention, there is provided a method of preventing adhesive bleed onto metal surfaces of a plurality of electrical conductors positioned on a dielectric substrate when positioning an electronic component onto the substrate and electrically coupling this component to the metal surfaces. The method includes contacting the metal surfaces with a chemical composition which comprises a minor amount of a surface-active agent and the remainder substantially being a non-reactive solvent.

According to another aspect of the invention, there is provided a circuitized substrate comprising a dielectric substrate including a plurality of electrical conductors thereon, selected ones of these conductors including a metal surface thereon, an electronic component positioned on the substrate and including a plurality of contact sites thereon, a quantity of adhesive substantially between the component and substrate for attaching the component to the substrate, and a plurality of electrically conductive members, selected ones of these electrically conductive members being bonded to corresponding, selected ones of the metal surfaces of the electrical conductors to electrically connect the component to the selected ones of said metal surfaces, the selected ones of the metal surfaces being contacted by a chemical composition which comprises a minor amount of a surface active agent and the remainder substantially being a non-reactive solvent, prior to the electrically conductive members being bonded to the corresponding, selected ones of the metal surfaces.

### BRIEF DESCRIPTION OF THE DRAWINGS

FIG. 1 is a top plan view, illustrating a substrate having conductive features thereon, including, among others, a component bonding pad and wire-bond pads;

FIG. 2 is a partial, enlarged view taken along the line 2-2 in FIG. 1;

FIG. 3 is a top plan view of the substrate of FIG. 1 with an electronic component mounted thereon and electrically coupled to at least one of the wire-bond pads; and

FIG. 4 is a partial, enlarged view (over the view of FIG. 3) as taken along the line 4-4 in FIG. 3, showing the various possible wire-bond connections of the invention.

### BEST MODE FOR CARRYING OUT THE INVENTION

For a better understanding of the present invention, together with other and further objects, advantages and capabilities thereof, reference is made to the following disclosure and appended claims.

By the term “circuitized substrate” as used herein to define the substrates onto which an electronic component may be positioned and electrically coupled is meant a dielectric substrate with at least component pad and a plurality of adjacent conductive pads which function as signal, ground and/or voltage (or power) pads to form elements for the substrate's circuitry. The substrate may also include additional circuit elements such as signal lines and/or pads.

By the term “electronic component” as used herein is meant any component capable of being positioned on and electrically coupled to a circuitized substrate. One known example of such a component is a semiconductor chip.

By the term “minor amount” as used herein when defining the percentage of the surface treatment agent of the composition defined herein is meant a percentage by weight of from about 0.0001 to about 0.001 percent.

In FIG. 1, there is shown a top plan view of a circuitized substrate 10 according to one embodiment of the invention. In this example, substrate 10 is a chip carrier, but may be a printed circuit board or other substrate designed for having an electronic component positioned thereon and electrically coupled to the circuitry thereof. Substrate 10 includes a dielectric substrate 11 which may be comprised of layers of conventional dielectric materials and conductive planes as part thereof. Examples of such dielectric materials include fiberglass-reinforced polymer resin (also known as “FR4”), polytetrafluoroethylene (e.g., Teflon, a trademark of E.I. DuPont deNemours & Company), dielectric material sold by the Assignee of the present invention under the name DriClad (a trademark of Assignee Endicott Interconnect Technologies, Inc.), selected photo-imageable materials, polyimide, and others known in the art. The conductive planes may provide signal, power (voltage) or ground functions, as is known for circuitized substrates, and are typically of copper or copper alloy material. These planes and layers are now shown in the drawings, but understood to possibly comprise part of substrate 10 as is well known in the art. Further definition is not deemed necessary.

In the embodiment of FIG. 1, circuitized substrate 10 includes a plurality of electrical conductors on the upper (and possibly lower, if desired) external surface thereof. In the embodiment shown, these conductors include a central component bonding pad 12 which in turn is connected to a ground ring 14 by a plurality of spaced-apart fingers 16, a voltage (power) ring 18, as well as four separate patterns of wire-bond pads 20. The central chip bonding pad 12, ground ring 14, fingers 16, voltage ring 18, and wire bond pads 20, preferably are formed of metal, e.g., copper, and include a precious metal (e.g., gold, but may be palladium, platinum or silver) external surface. It should be noted that in this embodiment (and others), that the chip pad 12 is of metal, including having gold or other precious metal as part thereof. If such gold or other noble metal is not present, the affinity of the surface active agent defined herein may not perform to the optimum levels defined. In the broadest aspects of this invention, it may be possible not to utilize a pad 12 at all, as it may be possible to secure the desired electronic component directly to the upper dielectric surface.

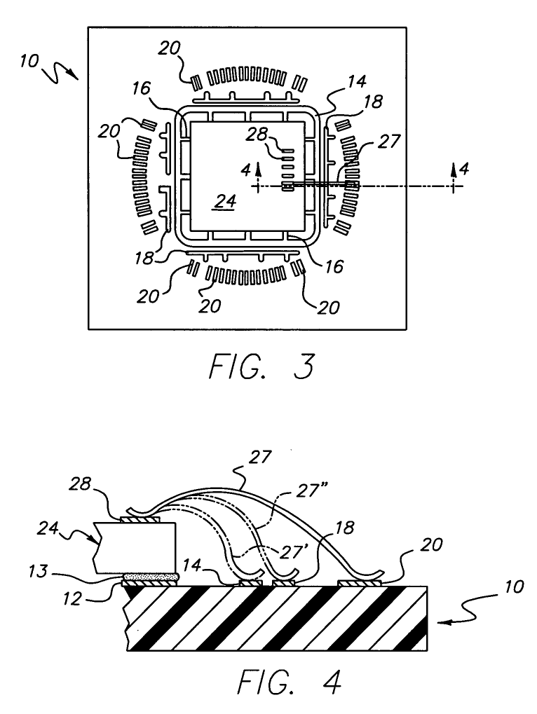

In the FIG. 1 embodiment, substrate 10 is designed particularly for having a semiconductor chip 24 (FIG. 3) positioned on pad 12 and secured thereto. The upper surface of the substrate is planar. The chip in turn is to be electrically coupled to selected ones of the electrical conductors, depending on the operational requirements thereof. In an alternative embodiment, substrate 10 may be designed with different patterns of electrical conductors such as outer pads 20 only, such that a different electronic component (e.g., a dual in-line processor (or DIP)) may be positioned with its metal projecting leads then bonded (e.g., soldered) to respective, selected ones of said outer pads. The teachings of this invention are thus applicable to other than chip carrier substrates designed to accommodate one or more semiconductor chips designed for having wire-bond connections between the chip(s) and the substrate's conductors.

To attach chip 24 (FIG. 3), an adhesive 13 is applied to the surface of the central chip bonding pad 12, and the chip is then positioned as shown in FIGS. 3 and 4. An adhesive usable for this bonding of the chip to the substrate's upper surface is an epoxy adhesive sold under the product designation “EPO-TEK H2OS-P” by Epoxy Technology of 14 Fortune Drive, Billerica, Mass. This electrical adhesive includes from sixty to seventy-five percent by weight silver flake (particle sizes less than or equal to twenty microns), has a low temperature cure of eighty degrees Celsius (hereinafter also simply C) at four hours, and is particularly suited for chip bonding. It also possesses a glass transition temperature (Tg) of eighty degrees C., a Shore D rating of 61 and a degradation temperature of as high as 429 degrees C. Another adhesive suitable for bonding chip 24 is a two part epoxy adhesive sold under the product designation “Ablebond 965-IL” by the Ablestick Corporation, having a place of business at 48/52, Punjabi Bagh (W) New Delhi—110026, Delhi, India. This adhesive, like theone above, also includes a silver filler, and is thus electrically conductive. Further, it has a temperature cure of 150 degrees C. for only one hour and a glass transition temperature (Tg) of eighty-five degrees C.

During the chip bonding process, there is a tendency for the adhesive to bleed and spread out from the bonding pad 12 surface onto the fingers 16 and the attached ground ring 14. Ground ring 14 is the first wire-bondable gold surface (meaning that one or more wires 27 from chip 24 may be wire-bonded directly thereto) that the chip adhesive comes in contact with but, depending on how the substrate is configured, the gold surfaces of ring 18 and the wire-bond pads 20 may also be affected. This is because these gold surfaces (being uncontaminated) possess an extremely high surface tension (e.g., in the range of 1,200 to 1,500 dynes/cm.), which is higher than the surface tension of the epoxy and, thus, the epoxy, or components thereof, will tend to bleed thereon, thereby wetting these surfaces. As a result, the subsequent wire-bonding process, to include wire-bonding wires to ground ring 14, voltage ring 18 and wire-bond (signal) pads 20, may result in poor or perhaps no bonds being formed on these surfaces, and thereby a defective product. In one example, the extent of adhesive bleed was measured by dispensing dots of the adhesive onto the gold surfaces of pad 12 then subjecting these to an established cure cycle. The maximum distances of spread were then determined using a microscope and measuring from the outer dispense edge.

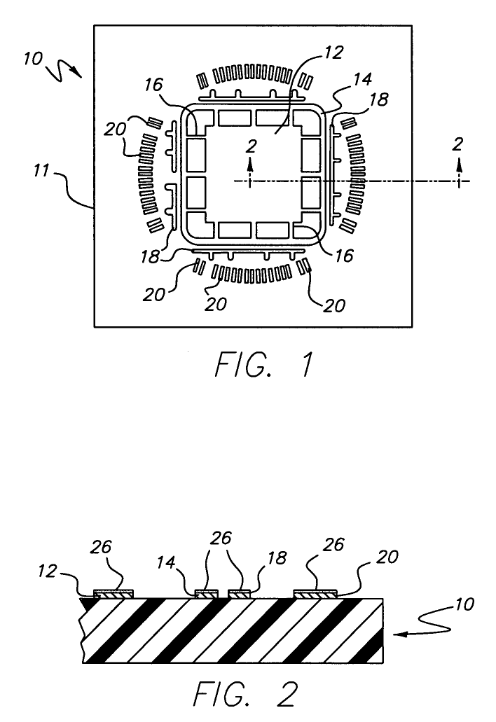

To overcome this bleeding problem, the upper gold surfaces of central chip bonding pad 12, ground ring 14, fingers 16, voltage ring 18, and wire bond pads 20, are treated with a chemical composition comprised of a minor amount of a surface active agent and the remainder substantially a non-reactive solvent. This chemical composition preferably is applied either by spraying or dipping or otherwise coating the entire surface of the substrate 10 with the chemical composition. In one example, the substrate was dipped into the chemical composition for a period of one minute, following which it was twice rinsed with de-ionized water for periods of thirty and 120 seconds, respectively. Following the rinse, the substrate was dried at eighty degrees C. for a period of fifteen minutes in a conventional oven. The chemical composition is generally characterized by a group (the surface active agent) that has an affinity to bond to gold or other noble metal, and is connected to one or more hydrocarbon groups. Preferably, these groups that bond to the gold are thiol (a preferred thiol being 1-octadecanethiol). A preferred non-reactive solvent is from the alcohol group, an especially preferred alcohol being methanol. In one example, the thiol comprises from about 0.0001 to about 0.001 percent by weight of the chemical composition while the methanol comprises from about 99.9990 to about 99.9999 percent by weight of the chemical composition. In a more particular example, the thiol comprises about 0.00036 percent by weight of the chemical composition and the methanol comprises about 99.99964 percent by weight of the chemical composition. It is understood that the invention is not limited to these particular percentages, as others are possible, as are other elements (e.g., a different alcohol such as linear or branched alcohols that have boiling points below 100 degrees C. in place of the methanol). Using the chemical composition above, the substrate's conductor surfaces were exposed to the composition for a period of from about one minute to about six minutes at a temperature of about twenty degrees C. As a result, a thin “modification” layer 26 (FIG. 2) comprised primarily of the thiol, remains on the metal surfaces. The methanol is quickly evaporated off, as soon as within one minute from terminating surface exposure. It is thus seen that this process may be accomplished in relatively quick time, rendering the method defined herein particularly suited for mass production.

As a result of this surface treatment, the gold surfaces each take on the characteristics of the hydrocarbon surface, which will in turn possess a surface tension significantly lower than that of the epoxy adhesive. In one example, the surface tension may be as low as only about 20 dynes/cm, which is lower than the aforementioned surface tension of the adhesive used. The thin “modification” layers 26 on the gold surfaces, as shown in FIG. 2, will protect these gold surfaces from any bleed from the adhesive wetting the gold surfaces as part of the chip bonding procedure. Of further significance, these thin thiol layers will not form on the external surface of the organic material which is part of substrate 10. It has also been learned that such layers will remain on the gold surfaces for months, in the event that subsequent wire-bonding is not meant to occur for such a prolonged period (this will therefore allow the substrate customer desiring to perform his/her own wire-bonding operations to store the substrates for such a period before undertaking the wire-bonding). It should also be added that when the modification layers 26 are subjected to subsequent wire-bonding processing in a relatively short period of time (e.g., in less than thirty seconds), the layers 26 will not form what are defined as “Self-Assembled Monolayers” (or SAMs) of the type described in aforementioned U.S. Pat. No. 6,252,307. Such formation may occur, however, following a prolonged period of non-activity with respect to these modification layers 26. Such formation is dependent on the amounts of the chemical composition (and especially the surface active agent component) applied onto the surfaces, and the remaining thiol.

Following the above steps, it is now desired to perform the aforementioned wire-bonding of wires 27 (only one shown in FIG. 3 for illustration purposes) to selected ones of the metal (gold) surfaces of wire-bond pads 20, ground ring 14 and/or voltage ring 18. In FIG. 3, each of these surfaces is shown as being bonded to, as is possible using the teachings herein (wire 27 providing connection to pad 20, while wire 27′ provides connection to ground ring 14 and wire 27″ connects to voltage ring 18. Each wire in turn is also connected to a respective contact site 28 (only that used by wire 27 shown in FIG. 3, it being understood that other sites 28 lie directly behind and in line with site 28). As is known, wire-bonding of the type used in chip carriers as shown herein is performed at elevated temperatures, and in the present example, at a temperature of at least about 120 degrees C. (and higher if needed). As a result, the surface active agent layers 26 will desorb from the various gold surfaces and allow the wire-bonds to effectively occur.

With respect to the upper surface of chip bonding pad 12, if also of gold, the chemical composition defined above, being of such minute quantities remaining on the pad's upper surface, has proven to be compatible with the adhesive 13, with mixing between the two elements occurring. The result of said mixing has had no deleterious effects on the bonding capabilities of the adhesive.

Thus there has been shown and described a process for preventing adhesive bleed onto the precious metal surfaces of conductive members such as wire-bond pads and the like on circuitized substrates. The method defined herein may be performed in relatively quick time and in a relatively facile manner. Further, the method as defined herein uses a surface active agent that does not require self assembly to yield a similar effect. Even further, pads and other gold-coated areas may co-exist on the same plane of a part, without spreading of adhesive components if the method as defined herein is used. This feature alone eliminates the need for physical dams in the original design. A product in the form of a circuitized substrate made using this method has also been shown and described.

While there have been shown and described what at present are considered the preferred embodiments of the invention, it will be obvious to those skilled in the art that various changes and modifications may be made therein without departing from the scope of the invention as defined by the appended claims.

What is claimed is:

1. A method of preventing adhesive bleed onto metal surfaces of a plurality of electrical conductors positioned on a dielectric substrate when positioning an electronic component onto said dielectric substrate and electrically coupling said electronic component to said metal surfaces, said method including contacting said metal surfaces with a chemical composition wherein said chemical composition comprises a minor amount of a surface active agent and the remainder substantially being a non-reactive solvent.

2. The method as defined in claim 1 wherein said surface active agent comprises thiol.

3. The method as defined in claim 2 wherein said thiol is 1-octadecanethiol.

4. The method as defined in claim 2 wherein said non-reactive solvent comprises an alcohol.

5. The method as defined in claim 4 wherein alcohol is methanol.

6. The method as defined in claim 5 wherein said thiol comprises from about 0.0001 to about 0.001 percent by weight of said chemical composition and said methanol comprises from about 99.9990 to about 99.9999 percent by weight of said chemical composition.

7. The method of claim 6 wherein said thiol comprises about 0.00036 percent by weight of said chemical composition and said methanol comprises about 99.99964 percent by weight of said chemical composition.

8. The method of claim 1 further including bonding at least one electrically conductive member to at least one of said metal surfaces of said electrical conductors following said contacting of said metal surfaces with said chemical composition.

9. The method of claim 8 wherein said at least one electrically conductive member comprises a wire and said bonding to said at least one of said metal surfaces of said electrical conductors is accomplished using a wire-bonding procedure.

10. The method of claim 1 wherein said metal surfaces are comprised of a precious metal, said non-reactive solvent of said composition being substantially completed evaporated from said metal surfaces within a relatively brief time period following said contacting of said metal surfaces with said chemical composition.

11. The method of claim 10 wherein said relatively brief time period is from about one to about three minutes.

12. A circuitized substrate comprising:
a dielectric substrate including a plurality of electrical conductors thereon, selected ones of said electrical conductors including a metal surface thereon;
an electronic component positioned on said dielectric substrate and including a plurality of contact sites thereon;
a quantity of adhesive substantially between said electronic component and said dielectric substrate for attaching said electronic component to said dielectric substrate; and
a plurality of electrically conductive members, selected ones of said electrically conductive members being bonded to corresponding, selected ones of said metal surfaces of said electrical conductors to electrically connect said electronic component to said selected ones of said metal surfaces of said electrical conductors, said selected ones of said metal surfaces of said electrical conductors being contacted by a chemical composition wherein said chemical composition comprises a minor amount of a surface active agent and the remainder substantially being a non-reactive solvent prior to said electrically conductive members being bonded to corresponding, selected ones of said metal surfaces.

13. The circuitized substrate of claim 12 wherein said metal surfaces of said electrical conductors are comprised of gold.

14. The circuitized substrate of claim 12 wherein said electronic component is a semiconductor chip.

15. The circuitized substrate of claim 12 wherein said adhesive is an epoxy adhesive.

16. The circuitized substrate of claim 12 wherein said plurality of said electrically conductive members comprise wires.

17. The circuitized substrate of claim 16 wherein selected ones of said electrically conductive members are also bonded to selected ones of said contact sites of said electronic component, said electronic component being a semiconductor chip.

18. The invention of claim 12 wherein said circuitized substrate comprises a chip carrier.

19. The invention of claim 12 wherein said circuitized substrate comprises a printed circuit board.
